(19) United States
(12) Patent Application Publication
(10) Pub. No.: US 2026/0302608 A1
(43) Pub. Date: Oct. 1, 2026

(54) ANTENNA

(71) Applicant: UNIQCONN INC., Seongnam-si (KR)

(72) Inventors: Young Dong KIM, Hwaseong-si (KR); Dong Hun SHIN, Anyang-si (KR); Oh Seog CHOI, Hwaseong-si (KR); Dong Hun OH, Ansan-si (KR); Myung Hwa KIM, Hwaseong-si (KR)

(73) Assignee: UNIQCONN INC., Seongnam-si (KR)

(21) Appl. No.: 19/571,675

(22) Filed: Mar. 19, 2026

(30) Foreign Application Priority Data
Mar. 26, 2025 (KR) 10-2025-0038513

(51) Int. Cl. H01Q 1/52; H01Q 9/04; H01Q 21/06; H01Q 21/24

(52) U.S. Cl. CPC H01Q 1/523; H01Q 9/0428; H01Q 21/065; H01Q 21/24

(57) ABSTRACT

The present disclosure relates to an antenna. An antenna according to embodiments of the present disclosure includes a plurality of first antenna patches disposed in a first array on a printed circuit board (PCB), a plurality of second antenna patches disposed in a second array on the PCB, a first feeding network configured to electrically connect the plurality of first antenna patches on the PCB and supply a first antenna signal to each of the plurality of first antenna patches, and a second feeding network configured to electrically connect the plurality of second antenna patches on the PCB and supply a second antenna signal to each of the plurality of second antenna patches, wherein the plurality of second antenna patches are disposed outside a region surrounding the first array.

### CROSS-REFERENCE TO RELATED APPLICATION

This application claims priority to and the benefit of Korean Patent Application No. 10-2025-0038513, filed on Mar. 26, 2025, the disclosure of which is incorporated herein by reference in its entirety.

### BACKGROUND

### 1. Field of the Invention

The present disclosure relates to an antenna, and more particularly, to an antenna that transmits and receives circular polarization signals.

### 2. Discussion of Related Art

Recently, various communication technologies are being utilized to enable short-range communication between various devices. In particular, devices that perform various operations, such as medical devices and robots, require communication technologies in order to control the operation of mechanical devices. These communication technologies may be broadly classified into wired communication technology and wireless communication technology.

Wired communication technology is implemented by arranging lines that transmit electrical signals between mechanical devices. This wired communication technology is a technology that communicates using electrical signals transmitted through lines and thus has the advantage of having stable signal quality with less external interference. However, the wired communication technology communicates through physically connected lines and thus has the disadvantage of limiting device operation. In particular, this disadvantage is more prominent when mechanical devices rotate 360 degrees.

On the other hand, wireless communication technology is an alternative technology that can compensate for the above-described disadvantage of the wired communication technology. Here, the wireless communication technology is a communication technology that controls mechanical devices through transmitting and receiving antennas disposed in each mechanical device. This wireless communication technology is a technology that enables communication even between physically separated mechanical devices and thus is a technology that can increase the degree of freedom in the operation of mechanical devices. In addition, through the above-described feature, the wireless communication technology is a technology that can reduce damage due to abrasion between mechanical devices and also reduce maintenance costs. However, the wireless communication technology has the disadvantages of difficulty in stable signal transmission due to signal interference that occurs when signals are transmitted and received and a limited communication distance. In addition, the wireless communication technology has the disadvantage that signal interference may occur between antennas disposed in each mechanical device.

In order to solve the disadvantages of the above-described wireless communication technology, a dual circularly polarized (DCP) antenna was developed.

The DCP antenna refers to an antenna that transmits and receives circularly polarized signals such as a right-hand-circular-polarization (RHCP) signal and a left-hand-circular-polarization (LHCP) signal. In addition, through these features, the DCP antenna can transmit and receive signals with stable quality by reducing external interference. However, even with DCP antennas, interference between RHCP signals and LHCP signals is still a problem. In addition, the interference between RHCP signals and the LHCP signals is caused by electromagnetic interference due to signal distortion or an overlapping circuit structure.

Accordingly, in order to solve the above-described problems on the basis of the problems and the causes thereof of the DCP antenna, an antenna according to the present disclosure will be described below.

Meanwhile, the foregoing background art is technical information that the inventors possess for derivation of the present disclosure or acquired during the derivation process, and thus the technical information cannot necessarily be referred to as known technology disclosed to the general public prior to filing the present disclosure.

### RELATED ART DOCUMENT

### Patent Document

(Patent Document 1) Korean Patent Laid-Open Application No. 10-2024-0063507 (May 10, 2024)

### SUMMARY OF THE INVENTION

An object to be solved by the present disclosure is to provide an antenna that solves interference problem between right-hand-circular-polarization (RHCP) signals and the left-hand-circular-polarization (LHCP) signals of a dual circularly polarized (DCP) antenna.

Another problem to be solved by the present disclosure is to provide an antenna that reduces electromagnetic interference due to an overlapping structure between an RHCP signal transmission circuit and an LHCP signal transmission circuit inside a communication module.

Still another problem to be solved by the present disclosure is to provide an antenna that solves the problem of a limited communication distance between antennas disposed in each mechanical device when wireless communication technology is used.

The problems to be solved by the present disclosure are not limited to the above-described problems, and other problems that are not mentioned can be clearly understood by those skilled in the art from the following description.

According to an aspect of the present disclosure, there is provided an antenna including a plurality of first antenna patches disposed in a first array on a printed circuit board (PCB), a plurality of second antenna patches disposed in a second array on the PCB, a first feeding network configured to electrically connect the plurality of first antenna patches on the PCB and supply a first antenna signal to each of the plurality of first antenna patches, and a second feeding network configured to electrically connect the plurality of second antenna patches on the PCB and supply a second antenna signal to each of the plurality of second antenna patches, wherein the plurality of second antenna patches are disposed outside a region surrounding the first array.

According to another aspect of the present disclosure, there is provided an antenna including a plurality of first antenna patches disposed in a first array on a printed circuit board (PCB), a plurality of second antenna patches disposed in a second array on the PCB, a first feeding network configured to electrically connect the plurality of first antenna patches on the PCB and supply a first antenna signal to each of the plurality of first antenna patches, and a second feeding network configured to electrically connect the plurality of second antenna patches on the PCB and supply a second antenna signal to each of the plurality of second antenna patches, wherein the plurality of second antenna patches are disposed within a region surrounding the first array.

According to an embodiment of the present disclosure, the number of first antenna patches may be greater than the number of second antenna patches.

According to another embodiment of the present disclosure, the antenna may further include a plurality of ground layers disposed below each of the plurality of first antenna patches and the plurality of second antenna patches to correspond to each of the plurality of first antenna patches and the plurality of second antenna patches, a first bonding layer that bonds the plurality of first antenna patches, the plurality of second antenna patches, and the plurality of ground layers in an insulated manner, a plurality of director layers disposed above each of the plurality of first antenna patches and the plurality of second antenna patches to correspond to each of the plurality of first antenna patches and the plurality of second antenna patches, and a second bonding layer that bonds the plurality of first antenna patches, the plurality of second antenna patches, and the plurality of director layers in an insulated manner, wherein each of the plurality of director layers has a structure in which at least two directors are stacked vertically through a third bonding layer, and the second bonding layer is a prepreg layer.

According to still another embodiment of the present disclosure, the first antenna signal may be a transmission signal when the second antenna signal is a reception signal, and the first antenna signal may be a reception signal when the second antenna signal is a transmission signal.

According to yet another embodiment of the present disclosure, the second array may be disposed parallel to a straight line connecting at least two first antenna patches of the first array.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a plan view of an antenna according to one embodiment of the present disclosure;

FIG. 2 is a schematic block diagram illustrating the antenna according to one embodiment of the present disclosure;

FIG. 3 is a cross-sectional view along line III-III′ of FIG. 1;

FIG. 4 is a diagram illustrating a beam forming pattern of a transmitter of the antenna according to one embodiment of the present disclosure;

FIG. 5 is a diagram illustrating a beam forming pattern of a receiver of the antenna according to one embodiment of the present disclosure;

FIG. 6 is a schematic conceptual diagram illustrating a wireless communication method between mechanical devices using the antennas according to one embodiment of the present disclosure;

FIG. 7 is a schematic block diagram illustrating an antenna according to another embodiment of the present disclosure;

FIG. 8 is a schematic block diagram illustrating an antenna according to still another embodiment of the present disclosure; and

FIG. 9 is a schematic block diagram illustrating an antenna according to yet another embodiment of the present disclosure

### DETAILED DESCRIPTION OF EXEMPLARY EMBODIMENTS

Advantages and features of the present disclosure and methods for achieving them will be made clear from embodiments described in detail below with reference to the accompanying drawings. The present disclosure may, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains, and the present disclosure is defined by only the scope of the appended claims.

Shapes, sizes, ratios, angles, numbers, and the like disclosed in the drawings for describing the embodiments of the present disclosure are illustrative, and thus the present disclosure is not limited to the illustrated matters. Further, in the following description of the present disclosure, when a detailed description of a known related technology is determined to unnecessarily obscure the gist of the present disclosure, the detailed description thereof will be omitted. When terms “including,” “having,” “consisting of,” and the like mentioned in the present disclosure are used, other parts may be added unless the term “only” is used herein. When a component is expressed in the singular, the plural is included unless otherwise specified.

In analyzing a component, it is interpreted as including an error range even when there is no explicit description.

Although the terms “first,” “second,” and the like are used to describe various components, these components are not limited by these terms. These terms are used only to distinguish one component from another component. Therefore, a first component described below may also be a second component within the technical spirit of the present disclosure.

Unless otherwise specified, the same reference numerals refer to the same components throughout the present specification.

The individual features of the various embodiments of the present disclosure may be partially or entirely combined or combined with each other, and various technical connections and operations are possible, as can be readily understood by those skilled in the art, and the individual embodiments may be implemented independently of each other or may be implemented together in a related relationship.

Hereinafter, an antenna according to embodiments of the present disclosure will be described in detail below with reference to the accompanying drawings.

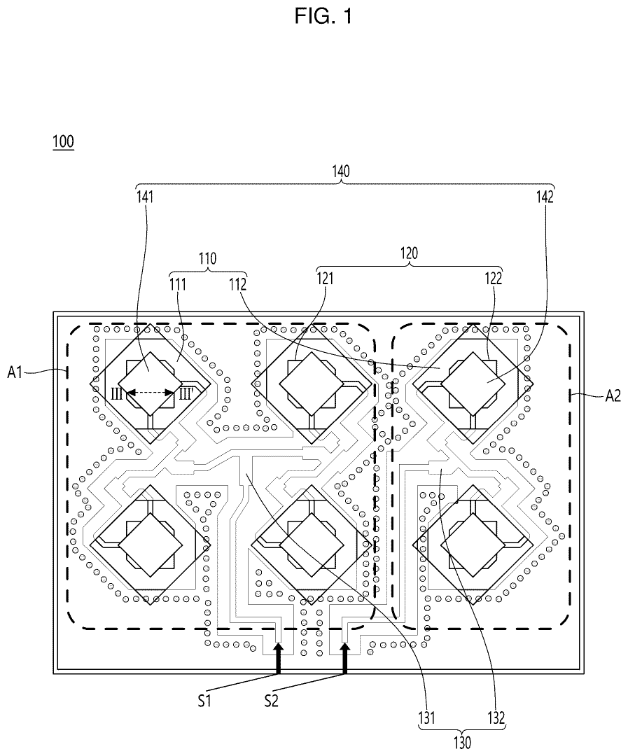

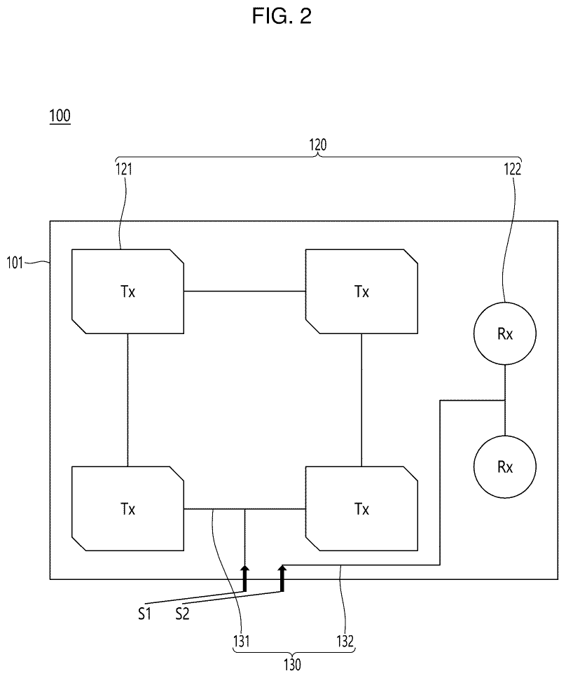

FIG. 1 is a plan view of an antenna 100 according to one embodiment of the present disclosure. In addition, FIG. 2 is a schematic block diagram illustrating the antenna 100 according to one embodiment of the present disclosure.

Referring to FIGS. 1 and 2, the antenna 100 according to one embodiment of the present disclosure includes a printed circuit board (PCB) 101, a plurality of ground layers 110, a plurality of antenna patches 120, a feeding network 130, and a plurality of director layers 140. Here, the plurality of ground layers 110, the plurality of antenna patches 120, the feeding network 130, and the plurality of director layers 140 may be formed on the PCB 101.

The PCB 101 refers to a board that mechanically supports electronic components and includes circuits that connect electrical signals between the electronic components. A material of the PCB 101 may be fiberglass-reinforced epoxy (FR-4), CEM-1, or CEM-3, which is based on glass fiber and an epoxy resin, or aluminum. In addition, the PCB 101 may be a flexible PCB based on polyimide or poly ethylene terephthalate (PET). Meanwhile, a circuit formed on the PCB 101 may be made of a conductor.

Each of the plurality of ground layers 110 refers to a conductive layer that provides a reference potential in the antenna 100. The plurality of ground layers 110 may include a plurality of first ground layers 111 disposed in a first region A1 and a plurality of second ground layers 112 disposed in a second region A2.

The plurality of first ground layers 111 may be disposed below a plurality of first antenna patches 121, which will be described below, to correspond to each of the plurality of first antenna patches 121. In addition, an area of each of the plurality of first ground layers 111 may be greater than an area of each of the plurality of first antenna patches 121.

The plurality of second ground layers 112 may be disposed below a plurality of second antenna patches 122, which will be described below, to correspond to each of the plurality of second antenna patches 122. In addition, an area of each of the plurality of second ground layers 112 may be greater than an area of each of the plurality of second antenna patches 122.

Each of the plurality of ground layers 110 may form a radiation pattern in a desired direction by reflecting a signal pattern radiated from each of the plurality of antenna patches 120 which will be described below. Therefore, the antenna 100 may improve the directionality of the signal radiated from the antenna 100 through the plurality of ground layers 110. Further, the antenna 100 may improve a gain thereof by reducing signal radiation in directions other than a radiation direction through the plurality of ground layers 110. Meanwhile, the antenna 100 may reflect a larger number of signals as the areas of the plurality of ground layers 110 increase. Therefore, the antenna 100 may improve the directionality of signals radiated through the plurality of ground layers 110 formed to be greater than the areas of the plurality of antenna patches 120. In addition, the antennas 100 may transmit and receive a large number of signals, thereby improving an antenna gain.

The plurality of antenna patches 120 include the plurality of first antenna patches 121 and the plurality of second antenna patches 122. The plurality of antenna patches 120 include four first antenna patches 121 and two second antenna patches 122. Here, the first antenna patches 121 may be transmitter antenna patches, and the second antenna patches 122 may be receiver antenna patches.

The plurality of antenna patches 120 are disposed in mechanical devices separated from each other so that an electromagnetic field may be radiated between the separated mechanical devices. Due to a radiation pattern of the electromagnetic field, the antenna 100 may transmit and receive radio signals through the plurality of antenna patches 120. Therefore, a mechanical device including the antenna 100 may perform wireless communication. Accordingly, a mechanical device in which the plurality of antenna patches 120 are disposed may not include a physical contact or a physical connection with another mechanical device in which the plurality of antenna patches 120 are disposed. Therefore, since there is no physical contact between the mechanical devices, wear or damage to the mechanical devices including the antennas 100 is reduced. Further, as the wear or damage to the mechanical devices is reduced, maintenance costs for the mechanical devices can also be reduced.

Each of the plurality of antenna patches 120 may be an antenna patch that performs ultra-high frequency wireless communication. For example, each of the plurality of antenna patches 120 may be an antenna patch having a center frequency of 60 GHz or higher. The ultra-high frequency wireless communication is a technology that may utilize a wide bandwidth in the ultra-high frequency band. Therefore, the antenna 100 in which the plurality of antenna patches 120 are disposed may transmit ultra-high-speed data and high-capacity data through ultra-high frequency wireless communication. Further, the antenna 100 in which the plurality of antenna patches 120 are disposed may transmit a strong signal in a specific direction through a beam forming technology utilizing ultra-high frequency wireless communication.

The plurality of first antenna patches 121 provided as four or more first antenna patches 121 may be disposed on the PCB 101. In addition, the plurality of first antenna patches 121 may be disposed in the form of a first array on the PCB 101. Although the first array is shown as a 2×2 array in the drawings, the present disclosure is not limited thereto, and an array in the form of a quadrangular shape may correspond to the first array. In this case, a region surrounding the plurality of first antenna patches 121 disposed in the form of a quadrangular shape are defined as a first region A1. Meanwhile, the number of first antenna patches 121 may be greater than the number of second antenna patches 122.

The plurality of second antenna patches 122 provided as two or more second antenna patches 122 may be disposed on the PCB 101. In addition, the plurality of second antenna patches 122 may be disposed in the form of a second array. Although the second array is shown as a 1×2 array in the drawings, the present disclosure is not limited thereto, and an array in the form of a linear shape may correspond to the second array. In this case, a region surrounding the plurality of second antenna patches 122 disposed in the form of a linear shape is defined as a second region A2. In addition, the second region A2 may be a region spaced a certain distance from one side of the first region A1. In addition, the plurality of second antenna patches 122 may be disposed outside the first region A1 of the plurality of first antenna patches 121. Further, the second array may be disposed parallel to a straight line connecting at least two first antenna patches 121 of the first array. In this case, the plurality of second antenna patches 122 disposed in the second array may be disposed at positions corresponding to arrangement positions of the plurality of first antenna patches 121 disposed in the first array. For example, the plurality of second antenna patches 122 may be disposed at side surfaces of at least two first antenna patches 121 disposed along one side of the first array.

The feeding network 130 includes a first feeding network 131 and a second feeding network 132. Here, the feeding network 130 refers to a circuit network formed on the PCB 101.

The first feeding network 131 may be a circuit network that electrically connects the plurality of first antenna patches 121. The first feeding network 131 may be a circuit network in the form of a quadrangular shape, which connects the centers of the plurality of first antenna patches 121. In addition, the first feeding network 131 may receive a first antenna signal S1 from an external component through a line structure connected to one side of the PCB 101. Here, the first antenna signal S1 may be a signal that controls the operation of the first antenna patches 121 in order to transmit data or that determines a pattern of a radiated beam.

The second feeding network 132 may be a circuit network that electrically connects the plurality of second antenna patches 122. The second feeding network 132 may be a circuit network in the form of a linear shape, which connects the centers of the plurality of second antenna patches 122. In addition, the second feeding network 132 may receive a second antenna signal S2 from an external component through a line structure connected to one side of the PCB 101. Here, the second antenna signal S2 may be a signal that controls the operation of the second antenna patches 122 in order to receive data or that determines a pattern of a radiated beam. Meanwhile, the line structure of the second feeding network 132 may be disposed not to overlap the line structure of the first feeding network 131.

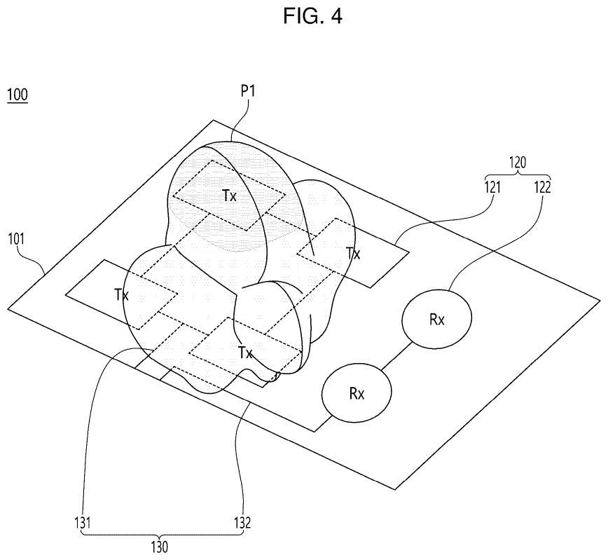

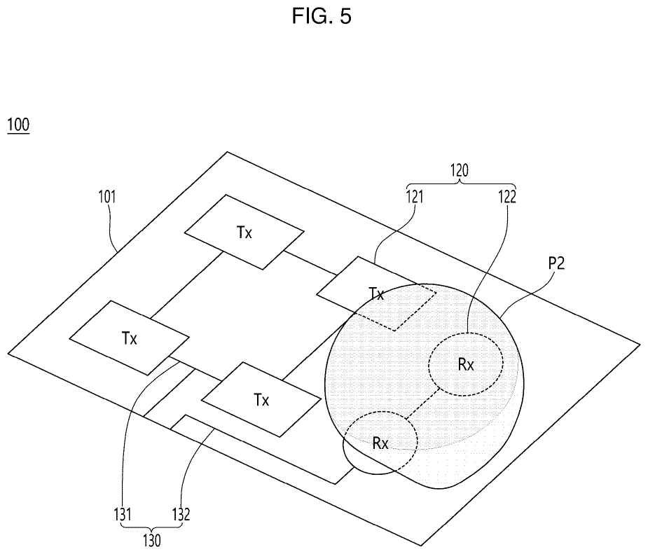

The first antenna signal S1 and second antenna signal S2 may be circular polarization signals. Specifically, the first antenna signal S1 may be a right-hand-circular-polarization (RHCP) signal, and the second antenna signal S2 may be a left-hand-circular-polarization (LHCP) signal. Depending on the types of antenna signals, a pattern and an area of the signals radiated from the antenna 100 may vary. Specifically, a shape and an area of the signal pattern radiated from the antenna will be described below with reference to FIGS. 4 and 5.

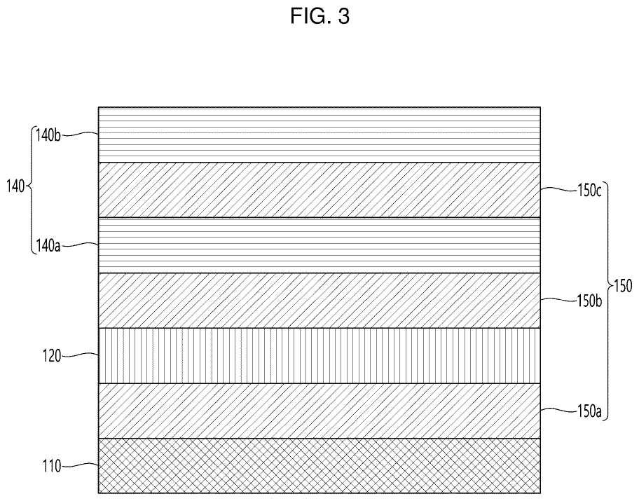

In the plurality of director layers 140, the director layer refers to a metal pattern that concentrates electromagnetic waves toward the radiation direction of the signal radiated from the antenna 100. In addition, each of the plurality of director layers 140 may include a plurality of directors that are stacked vertically. The stacked structure of the plurality of directors will be described below with reference to FIG. 3. Meanwhile, the plurality of director layers 140 may include a plurality of first director layers 141 and a plurality of second director layers 142, which are classified according to the arrangement structure of the plurality of antenna patches 120.

Specifically, each of the plurality of first director layers 141 may be disposed on the plurality of first antenna patches 121. In addition, each of the plurality of first director layers 141 may be disposed to correspond to each of the plurality of first antenna patches 121. In addition, the plurality of second director layers 142 may be disposed on the plurality of second antenna patches 122. In addition, each of the plurality of second director layers 142 may be disposed to correspond to each of the plurality of second antenna patches 122.

Each of the plurality of director layers 140 concentrates the signal radiated from the antenna 100 in a specific direction through a metal pattern that concentrates electromagnetic waves toward the signal radiation direction. In addition, the director layer 140 may reduce a beam width of the signal radiated from the plurality of antenna patches 120. In this way, the antenna 100 may improve the directionality of the radiated signal in a specific direction. In addition, since the antenna 100 improves the directionality of the radiated signal through the plurality of director layers 140, signal interference from the external environment is reduced and thus a signal-noise-ratio (SNR) can be improved. In addition, due to the above features, since the antenna 100 may transmit a signal to antennas disposed further away, an available communication distance with antennas disposed in other mechanical devices can be extended. Further, since the antenna 100 reduces signal radiation in directions other than the radiation direction through the plurality of director layers 140, a gain of the antenna 100 can be improved.

The plurality of ground layers 110, the plurality of antenna patches 120, the feeding network 130, and the plurality of director layers 140 may be respectively insulated from and bonded to each other through a bonding layer. The bonding layer will be described in detail below through the stacked structure of the antenna 100 shown in FIG. 3.

The antenna 100 according to one embodiment of the present disclosure has a single communication module structure in which the plurality of first antenna patches 121 that supply transmission signals and the plurality of second antenna patches 122 that supply reception signals are disposed on a flat surface of the single PCB 101. Therefore, according to the antenna 100, the number of communication modules disposed in the mechanical device may be less than that of communication modules in the case in which a transmitting communication module and a receiving communication module are manufactured separately. In addition, as the number of communication modules required for a mechanical device is reduced, the cost of manufacturing the mechanical device itself can be reduced. Meanwhile, the plurality of first antenna patches 121 and the plurality of second antenna patches 122 may be simultaneously formed on the PCB 101 through a single process operation. Therefore, according to the antenna 100, the number of process operations can be reduced. In addition, as the number of process operations is reduced, the process cost for the antenna 100 can be reduced.

Since the antenna 100 according to one embodiment of the present disclosure includes the plurality of first antenna patches 121 and the plurality of second antenna patches 122, which are spaced apart from each other, electromagnetic field interference between the plurality of first antenna patches 121 and the plurality of second antenna patches 122 is reduced so that signal interference therebetween can be reduced. In addition, as a separation distance between the plurality of first antenna patches 121 and the plurality of second antenna patches 122 increases, isolation for such signal interference can be increased. Meanwhile, since the line structure of the first feeding network 131 and the line structure of the second feeding network 132 do not overlap each other, the antenna 100 according to one embodiment of the present disclosure may prevent electromagnetic interference caused by overlapping line structures and improve isolation.

Since the antenna 100 according to one embodiment of the present disclosure includes the plurality of antenna patches 120, a magnitude or intensity of the signal radiated may be greater than when one antenna patch is included. In addition, a magnitude or intensity of the signal received by another antenna disposed in a third mechanical device may increase as the magnitude or intensity of the signal radiated by the antenna 100 increases. In this way, the antenna 100 may improve a gain thereof compared to an antenna in which one antenna patch is disposed.

The antenna 100 according to one embodiment of the present disclosure may generate a beam forming pattern by the first antenna signal S1 and a beam forming pattern by the second antenna signal S2, respectively, through an arrangement structure for a 2×2 array of the plurality of first antenna patches 121 and a 1×2 array of the plurality of second antenna patches 122. In addition, the antenna 100 may improve the directionality, SNR, and communication distance of the antenna signal through these beam forming patterns. This will be described in detail below with reference to FIGS. 4 to 5.

FIG. 3 is a cross-sectional view along line III-III′ of FIG. 1. Hereinafter, the stacked structure of the antenna 100 will be described below with reference to FIG. 3. Meanwhile, the description of the configuration described above with reference to FIGS. 1 and 2 differs from a configuration that will be described with reference to FIG. 3 only in the content regarding the plurality of director layers 140 and a plurality of bonding layers 150, and thus the duplicated content will be omitted, and a non-duplicated content will described below.

Referring to FIGS. 1 to 3, the antenna 100 according to one embodiment of the present disclosure has a stacked structure of the plurality of ground layers 110, the plurality of antenna patches 120, the feeding network 130, the plurality of director layers 140, and the plurality of bonding layers 150. Here, the plurality of bonding layers 150 may include a first bonding layer 150a, a second bonding layer 150b, and a third bonding layer 150c.

Referring to FIG. 3, the ground layer 110 may be insulated from and bonded to the antenna patch 120 through the first bonding layer 150a. In addition, the director layer 140 may be insulated from and bonded to the antenna patch 120 through the second bonding layer 150b. In this case, the director layer 140 may include at least two directors 140a and 140b. In addition, the two directors 140a and 140b may be insulated from and bonded to each other through at least one third bonding layer 150c. In addition, although not shown in FIG. 3, the feeding network disposed on the same planar surface as a layer of the antenna patch 120 may be insulated from and bonded to the ground layer 110 through the first bonding layer 150a. In addition, the feeding network may be insulated from and bonded to the director layer 140 through the second bonding layer 150b.

The second bonding layer 150b is a semi-cured layer and may be a prepreg layer. The prepreg layer is a glass fiber layer in which a resin is pre-impregnated and may be an insulating layer that is not completely cured. The prepreg layer may be cured by a pressure generated during a stacking process and heat applied during a manufacturing process. Therefore, the prepreg layer may firmly bond the antenna patch 120 and the director layer 140 in an insulated manner through the pressure or heat applied during the manufacturing process.

The antenna 100 according to one embodiment of the present disclosure includes at least two directors 140a and 140b in a vertically stacked structure so that the directionality of the radiated signal can be improved compared to the case in which only one director is disposed. Further, since the antenna 100 reduces signal loss in directions other than the radiation direction through the directors 140a and 140b, a gain of the antenna 100 can be improved. In addition, the antenna 100 may improve the directionality of the signal so that signal interference from the external environment can be reduced to improve an SNR. In addition, since the antenna 100 includes the directors 140a and 140b that improve the directionality of radiated signals in a specific direction, communication with other antennas disposed at a further distance can also be performed. That is, the antenna 100 may extend an available communication distance with antennas disposed in other mechanical devices.

FIG. 4 is a diagram illustrating a beam forming pattern of a transmitter of the antenna 100 according to one embodiment of the present disclosure.

Referring to FIG. 4, the transmitter of the antenna 100 according to one embodiment of the present disclosure may generate a beam forming pattern P1 having a narrower radiation shape than a radiation shape of a receiver through the plurality of first antenna patches 121 disposed in a first array arrangement. The beam forming pattern P1 formed to have a narrow radiation shape may have the strongest radiation shape in a signal transmission direction of the antenna 100. In this case, since the antenna 100 concentrates the signal in a certain direction through the beam forming pattern P1 formed to have a narrow radiation shape, the antenna 100 may improve the directionality of the transmitted signal. Therefore, the antenna 100 may improve the directionality of the transmitted signal and transmit the signal to other antennas located at a long distance. That is, the available communication distance between the antenna 100 and an antenna disposed in a different mechanical device may be increased. Further, the antenna 100 may improve a gain of the antenna 100 by reducing signal loss in directions other than the signal transmission direction through the improved directionality of the transmitted signal. Meanwhile, the antenna 100 is less affected by a magnetic material disposed around the antenna 100 through the beam forming pattern P1 formed to have a narrow radiation shape, and thus a separate additional material such as an absorber may not be required.

FIG. 5 is a diagram illustrating a beam forming pattern of a receiver of the antenna 100 according to one embodiment of the present disclosure.

Referring to FIG. 5, the receiver of the antenna 100 according to one embodiment of the present disclosure may generate a beam forming pattern P2 close to a widely formed spherical shape through the plurality of second antenna patches 122 disposed in a second array arrangement. In this case, the antenna 100 may easily receive external signals by utilizing the widely formed spherical beam forming pattern P2. Therefore, the antenna 100 may expand an available communication range by widening a reception area for the signal transmitted from the transmitter. Further, the antenna 100 may also improve an SNR by reducing the interference from external signals outside the pattern through the widely formed spherical beam forming pattern P2.

Meanwhile, referring to FIGS. 4 and 5, since the antenna 100 includes the plurality of first antenna patches 121 and the plurality of second antenna patches 122, which are spaced apart from each other, signal interference between the beam forming pattern of the transmitter and the beam forming pattern of the receiver may not occur due to isolation. Therefore, the antenna 100 can reduce signal interference between the transmitter and the receiver, improve the SNR, and expand the communication area thereof.

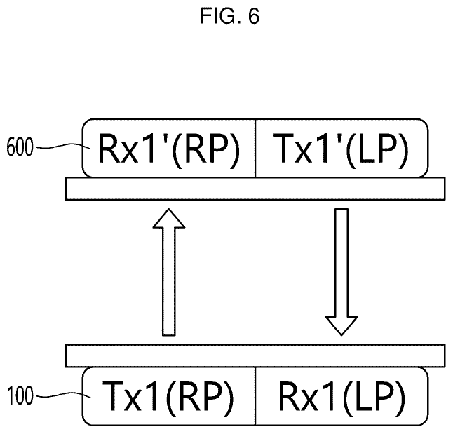

FIG. 6 is a schematic conceptual diagram illustrating a wireless communication method between mechanical devices using antennas 100 and 600 according to one embodiment of the present disclosure.

Referring to FIG. 6, each of the antennas 100 and 600 according to one embodiment of the present disclosure may be disposed in a corresponding one of the mechanical devices. In addition, the mechanical devices may be spaced a certain distance from and face each other. In this case, the antenna 100 disposed in one mechanical device may include a transmitter Tx1 and a receiver Rx1, and the antenna 600 disposed in another mechanical device may include a receiver Rx1′ and a transmitter Tx1′.

Since the receiver Rx1 of the antenna 100 disposed in one mechanical device receives an LHCP signal, the receiver Rx1 may receive only the LHCP signal transmitted from the transmitter Tx1′ of the antenna 600 disposed in another mechanical device. Similarly, since the receiver Rx1′ of the antenna 600 disposed in another mechanical device receives an RHCP signal, the receiver Rx1′ may receive only the RHCP signal transmitted from the transmitter Tx1 of the antenna 100 disposed in one mechanical device. Therefore, a signal transmitted from the transmitter Tx1 of the antenna 100 disposed in one mechanical device may be received by the receiver Rx1′ of the antenna 600 disposed in another mechanical device, and a signal transmitted from the transmitter Tx1′ of the antenna 600 disposed in another mechanical device may be received by the receiver Rx1 of the antenna 100 disposed in one mechanical device. That is, the polarization directions of the transmitters Tx1 and Tx1′ and the receivers Rx1 and Rx1′, which are intended to communicate with each other, may be the same direction.

Since the signals transmitted and received between the antennas 100 and 600 are fixed, the mechanical devices in which the antennas 100 and 600 are disposed may smoothly perform wireless communication even during a rotational operation of each mechanical device. Meanwhile, each of the antennas 100 and 600 may improve the directionality of the signal radiated through the plurality of first antenna patches disposed in a 2×2 array and the plurality of second antenna patches disposed in a 1×2 array so that the available communication distance between the antennas 100 and 600 can expand. Therefore, the mechanical devices in which the antennas 100 and 600 are disposed may communicate with each other smoothly in a wireless manner even when the mechanical devices are separated by a long distance. Further, since the radiation pattern at the receiver is wider than that at the transmitter, the area of the receiver and the number of antenna patches included in the receiver may be less than the area of the transmitter and the number of antenna patches included in the transmitter. That is, the receiver may be implemented in a relatively narrow area compared to the transmitter. Consequently, the structure, size and area of antenna 100 can be reduced.

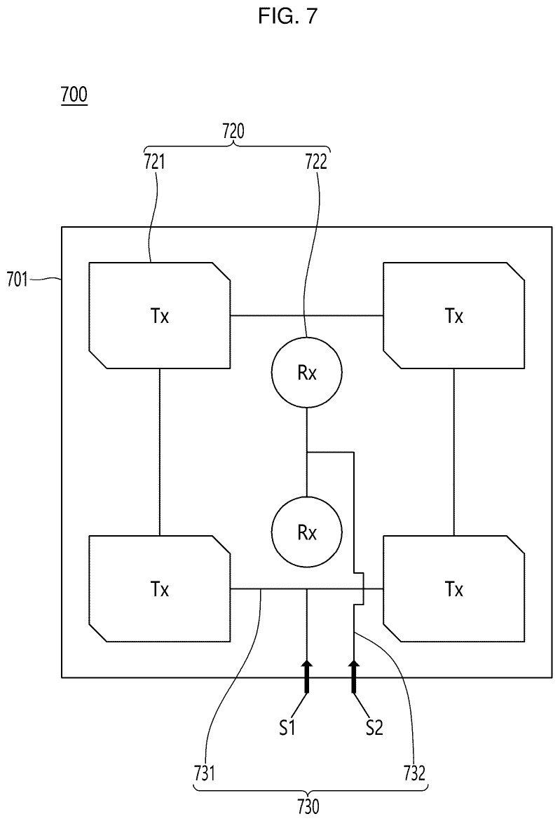

FIG. 7 is a schematic block diagram illustrating an antenna 700 according to another embodiment of the present disclosure. Meanwhile, FIG. 7 is different from FIGS. 1 and 2 only in an arrangement structure of a plurality of antenna patches 720, and descriptions of other configurations are substantially the same, and thus the duplicate content will be omitted, and the difference will be described below.

Referring to FIG. 7, in the antenna 700 according to another embodiment of the present disclosure, a plurality of second antenna patches 722 disposed in the form of a second array may be disposed within a first region of a plurality of first antenna patches 721 disposed in the form of a first array. That is, the plurality of second antenna patches 722 corresponding to a receiver may be disposed within the first region surrounded by the plurality of first antenna patches 721 corresponding to a transmitter. Further, the plurality of second antenna patches 722 may be spaced apart from the plurality of first antenna patches 721. Meanwhile, the second array may be disposed parallel to a straight line connecting at least two first antenna patches 721 of the first array.

A second feeding network 732 may receive a second antenna signal S2 through a line structure connected to one side of a PCB 701. In this case, in the second feeding network 732, the line connected to one side of the PCB 701 may partially overlap the line structure of a first feeding network 731.

In the antenna 700 according to another embodiment of the present disclosure, since the plurality of second antenna patches 722 are disposed within the first region of the plurality of first antenna patches 721, a beam forming pattern for the first antenna patches 721 in a 2×2 array and a beam forming pattern for the second antenna patches 722 in a 1×2 array may overlap each other. Therefore, according to the antenna 700, the beam forming pattern of each of the transmitter and the receiver may be formed within the first region of the plurality of first antenna patches 721. In addition, since the beam forming pattern of the antenna 700 can be formed within the first region of the plurality of first antenna patches 721, the antenna 700 can be manufactured in a size of the first region. That is, the antenna 700 can be miniaturized.

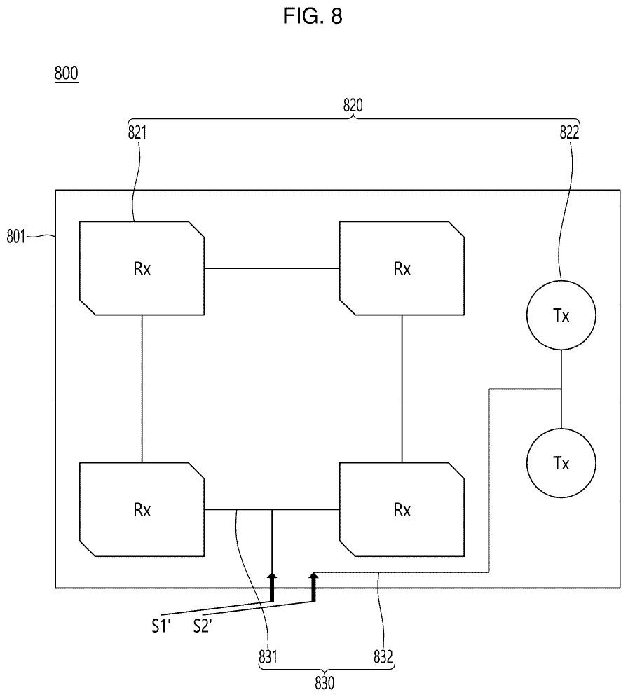

FIG. 8 is a schematic block diagram illustrating an antenna 800 according to still another embodiment of the present disclosure. Meanwhile, FIG. 8 is different from FIGS. 1 and 2 only in the types of signals applied to a first antenna signal S1′ and a second antenna signal S2′, and descriptions of other configurations are substantially the same, and thus the duplicate content will be omitted, and the difference will be described below.

In the antenna 800 according to still another embodiment of the present disclosure, the first antenna signal S1′ may be a signal that controls the operation of first antenna patches 821 in order to receive data or that determines a pattern of a beam that is radiated. In addition, the second antenna signal S2′ may be a signal that controls the operation of second antenna patches 822 in order to transmit data or that determines a pattern of a beam that is radiated. Further, the first antenna signal S1′ may be an LHCP signal, and the second antenna signal S2′ may be an RHCP signal. Therefore, according to the antenna 800, the plurality of first antenna patches 821 may generate a beam forming pattern for a received signal, and the plurality of second antenna patches 822 may generate a beam forming pattern for a transmitted signal.

Since the antenna 800 according to still another embodiment of the present disclosure includes the plurality of first antenna patches 821 and the plurality of second antenna patches 822, which are spaced apart from each other, interference between the beam forming pattern generated by the first antenna signal S1′ and the beam forming pattern generated by the second antenna signal S2′ can be reduced. Meanwhile, since the antenna 800 includes the plurality of first antenna patches 821 disposed in the 2×2 array, the antenna 800 may generate a beam forming pattern in a narrowly formed radiation shape. Due to the beam forming pattern in a narrowly formed radiation shape, the antenna 800 can improve the directionality for the received signal and reduce interference by the external environment, thereby improving an SNR and expanding a communication area of the antenna 800. Meanwhile, since the antenna 800 includes the plurality of second antenna patches 822 disposed in the 1×2 array, the antenna 800 may generate a beam forming pattern in a widely formed spherical shape. Due to the wide beam forming pattern in a widely formed spherical shape, the antenna 800 can reduce the influence and interference by the external environment by transmitting a transmission signal over a wide area, thereby improving a gain of the antenna 800. In addition, the antenna 800 may form a wide overlap area between the beam forming pattern for the transmission signal of the antenna 800 and a beam forming pattern for a reception signal of another antenna by transmitting the transmission signal over a wide area through the beam forming pattern in the widely formed spherical shape. In this way, as the overlapping area of the beam forming patterns for the two signals is formed to be wide, an available communication area of the antenna 800 can expand.

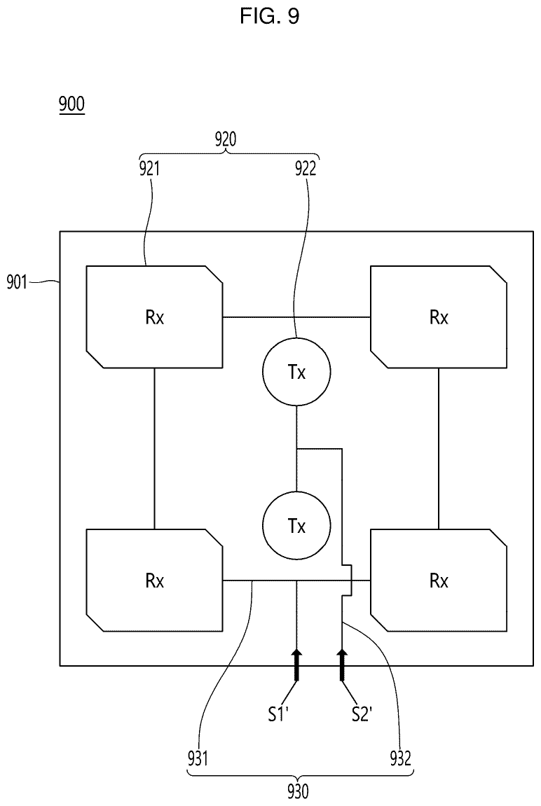

FIG. 9 is a schematic block diagram illustrating an antenna 900 according to yet another embodiment of the present disclosure. Meanwhile, FIG. 9 is different from FIGS. 1 and 2 only in an arrangement structure of a plurality of antenna patches 920 and the types of signals applied to a first antenna signal S1′ and a second antenna signal S2′, and descriptions of other configurations are substantially the same, and thus the duplicate content will be omitted, and the difference will be described below.

In the antenna 900 according to yet another embodiment of the present disclosure, a plurality of second antenna patches 922 disposed in the form of a second array may be disposed within a first region of a plurality of first antenna patches 921 disposed in the form of a first array. Further, the plurality of second antenna patches 922 may be spaced apart from the plurality of first antenna patches 921. Meanwhile, the second array may be disposed parallel to a straight line connecting at least two first antenna patches 921 of the first array.

A second feeding network 932 may receive a second antenna signal S2′ through a line structure connected to one side of a PCB 901. In this case, in the second feeding network 932, the line connected to one side of the PCB 901 may partially overlap the line structure of a first feeding network 931.

In the antenna 900 according to yet another embodiment of the present disclosure, the first antenna signal S1′ may be a signal that controls the operation of first antenna patches 921 in order to receive data or that determines a pattern of a beam that is radiated. In addition, the second antenna signal S2′ may be a signal that controls the operation of second antenna patches 922 in order to transmit data or that determines a pattern of a beam that is radiated. Further, the first antenna signal S1′ may be an LHCP signal, and the second antenna signal S2′ may be an RHCP signal. Therefore, according to the antenna 900, the plurality of first antenna patches 921 may generate a beam forming pattern for a received signal, and the plurality of second antenna patches 922 may generate a beam forming pattern for a transmitted signal.

In the antenna 900 according to yet another embodiment of the present disclosure, since the plurality of second antenna patches 922 are disposed within the first region of the plurality of first antenna patches 921, a beam forming pattern for the first antenna patches 921 in a 2×2 array and a beam forming pattern for the second antenna patches 922 in a 1×2 array may overlap each other. Therefore, according to the antenna 900, the beam forming pattern of each of the transmitter and the receiver may be formed within the first region of the plurality of first antenna patches 921. In addition, since the beam forming pattern of the antenna 900 can be formed within the first region of the plurality of first antenna patches 921, the antenna 900 can be manufactured in a size of the first region. That is, the antenna 900 can be miniaturized.

An antenna according to any one of the problem solving means of the present disclosure includes the plurality of second antenna patches disposed to be spaced a certain distance from the plurality of first antenna patches in electrically insulated state so that electromagnetic interference between a plurality of first antenna patches and a plurality of second antenna patches can be reduced. In this way, since the electromagnetic interference between the antenna patches is reduced, interference between polarized signals can also be reduced.

Since an antenna according to any one of the problem solving means of the present disclosure includes a first feeding network and a second feeding network, which have an independent line structure, polarization signal interference between a plurality of first antenna patches and a plurality of second antenna patches can be reduced.

Since an antenna according to any one of the problem solving means of the present disclosure includes a plurality of first antenna patches disposed in a quadrangular first array in a transmitter and a plurality of second antenna patches disposed in a linear second array in a receiver, a narrow beam forming pattern for the plurality of first antenna patches and a wide beam forming pattern for the plurality of second antenna patches can be generated. In this way, since a narrow beam forming pattern for the plurality of first antenna patches and a wide beam forming pattern for the plurality of second antenna patches are generated, the directionality of a transmission signal can be improved, and a reception area for a reception signal can be widened. Further, by including a transmitter that transmits a transmission signal with high directionality and a receiver that forms a wide reception area, an available communication distance with an antenna disposed in another mechanical device can be improved.

In addition, since an antenna according to any one of the problem solving means of the present disclosure generates a narrow beam forming pattern through a plurality of first antenna patches disposed in a quadrangular first array and a wide beam forming pattern through a plurality of second antenna patches disposed in a linear second array, signal interference due to the external environment can be reduced. In this way, by reducing the signal interference due to the external environment, a signal-noise-ratio (SNR) and an antenna gain can also be improved.

In addition, since an antenna according to any one of the problem solving means of the present disclosure includes a plurality of second antenna patches disposed inside a plurality of first antenna patches, beam forming patterns generated by a transmitter and a receiver can be formed inside the plurality of first antenna patches. In this way, by forming the beam forming patterns generated by the transmitter and the receiver within the plurality of first antenna patches, the antenna can be manufactured in a size corresponding to an area occupied by the plurality of first antenna patches. In addition, since the antenna is manufactured in a size corresponding to an area occupied by the plurality of first antenna patches, the size of the antenna can be miniaturized.

The effects obtained by the present disclosure are not limited to the above-mentioned effects, and other effects which are not mentioned can be clearly understood by those skilled in the art to which the present invention pertains from the above description.

Although embodiments of the present disclosure have been described in more detail with reference to the accompanying drawings, the present disclosure is not necessarily limited to these embodiments and may be variously modified without departing from the technical spirit of the present disclosure. Therefore, the embodiments disclosed herein are intended to explain rather than limit the technical concept of the present disclosure, and the scope of the technical concept of the present disclosure is not limited to these embodiments. Therefore, it should be understood that the above-described embodiments are not restrictive but illustrative in all aspects. The scope of protection of the present disclosure should be construed by the appended claims, and all technical concepts within a scope equivalent thereto should be construed as being included in the scope of the present disclosure.

What is claimed is:

1. An antenna comprising:
a plurality of first antenna patches disposed in a first array on a printed circuit board (PCB);
a plurality of second antenna patches disposed in a second array on the PCB;
a first feeding network configured to electrically connect the plurality of first antenna patches on the PCB and supply a first antenna signal to each of the plurality of first antenna patches; and
a second feeding network configured to electrically connect the plurality of second antenna patches on the PCB and supply a second antenna signal to each of the plurality of second antenna patches,
wherein the plurality of second antenna patches are disposed outside a region surrounding the first array.

2. An antenna comprising:
a plurality of first antenna patches disposed in a first array on a printed circuit board (PCB);
a plurality of second antenna patches disposed in a second array on the PCB;
a first feeding network configured to electrically connect the plurality of first antenna patches on the PCB and supply a first antenna signal to each of the plurality of first antenna patches; and
a second feeding network configured to electrically connect the plurality of second antenna patches on the PCB and supply a second antenna signal to each of the plurality of second antenna patches,
wherein the plurality of second antenna patches are disposed within a region surrounding the first array.

3. The antenna of claim 1, wherein the number of first antenna patches is greater than the number of second antenna patches.

4. The antenna of claim 3, further comprising:
a plurality of ground layers disposed below each of the plurality of first antenna patches and the plurality of second antenna patches to correspond to each of the plurality of first antenna patches and the plurality of second antenna patches;
a first bonding layer that bonds the plurality of first antenna patches, the plurality of second antenna patches, and the plurality of ground layers in an insulated manner;
a plurality of director layers disposed above each of the plurality of first antenna patches and the plurality of second antenna patches to correspond to each of the plurality of first antenna patches and the plurality of second antenna patches; and
a second bonding layer that bonds the plurality of first antenna patches, the plurality of second antenna patches, and the plurality of director layers in an insulated manner,
wherein each of the plurality of director layers has a structure in which at least two directors are stacked vertically through a third bonding layer, and
the second bonding layer is a prepreg layer.

5. The antenna of claim 1, wherein:
the first antenna signal is a transmission signal when the second antenna signal is a reception signal; and
the first antenna signal is a reception signal when the second antenna signal is a transmission signal.

6. The antenna of claim 1, wherein the second array is disposed parallel to a straight line connecting at least two first antenna patches of the first array.

7. The antenna of claim 2, wherein the number of first antenna patches is greater than the number of second antenna patches.

8. The antenna of claim 7, further comprising:
a plurality of ground layers disposed below each of the plurality of first antenna patches and the plurality of second antenna patches to correspond to each of the plurality of first antenna patches and the plurality of second antenna patches;
a first bonding layer that bonds the plurality of first antenna patches, the plurality of second antenna patches, and the plurality of ground layers in an insulated manner;
a plurality of director layers disposed above each of the plurality of first antenna patches and the plurality of second antenna patches to correspond to each of the plurality of first antenna patches and the plurality of second antenna patches; and
a second bonding layer that bonds the plurality of first antenna patches, the plurality of second antenna patches, and the plurality of director layers in an insulated manner,
wherein each of the plurality of director layers has a structure in which at least two directors are stacked vertically through a third bonding layer, and
the second bonding layer is a prepreg layer.

9. The antenna of claim 2, wherein:
the first antenna signal is a transmission signal when the second antenna signal is a reception signal; and
the first antenna signal is a reception signal when the second antenna signal is a transmission signal.

10. The antenna of claim 2, wherein the second array is disposed parallel to a straight line connecting at least two first antenna patches of the first array.
